(19) United States
(12) Patent Application Publication
(10) Pub. No.: US 2025/0176110 A1
(43) Pub. Date: May 29, 2025

(54) AIR-PERMEABLE STRETCHABLE CIRCUIT WHICH CAN BE ACTIVATED BY STAMPING, PREPARATION METHOD AND USE THEREOF

(71) Applicant: SOOCHOW UNIVERSITY, Suzhou (CN)

(72) Inventors: Feng YAN, Wujiang (CN); Sijie ZHENG, Wujiang (CN)

(21) Appl. No.: 18/765,298

(22) Filed: Jul. 7, 2024

Related U.S. Application Data
(63) Continuation of application No. PCT/CN2024/075400, filed on Feb. 2, 2024.

(30) Foreign Application Priority Data
Nov. 28, 2023 (CN) 202311604122.7

(51) Int. Cl. H05K 3/12; D01D 1/02; D01D 1/06; D01D 5/00; D04H 1/4382; D04H 1/728; H05K 1/03

(52) U.S. Cl. CPC H05K 3/1275; D01D 1/02; D01D 1/065; D01D 5/003; D01D 5/0069; D04H 1/43838; D04H 1/728; H05K 1/0366; D10B 2401/041; D10B 2401/061; D10B 2401/16; D10B 2403/0243; D10B 2403/033

(57) ABSTRACT

The present invention relates to an air-permeable stretchable circuit, which can be activated by stamping, preparation method and use thereof, belonging to the field of flexible electronic technology. The preparation method includes steps of: dissolving a thermoplastic polymer in a solvent, then adding liquid metal particles and mixing to obtain a mixed solution; performing electrospinning on the mixed solution to prepare a nanofiber membrane; performing stamping on the nanofiber membrane with a stamping mould having a circuit pattern, to obtain the air-permeable stretchable circuit. The invention ensures air-permeability and stretchability through using nanofiber membranes. Due to the matching diameters of the liquid metal particles and the fibers, stamping can cause the liquid metal inside the nanofibers to overflow and form conductive paths, thereby achieving high-precision preparation of circuits.

This application is a Continuation Application of PCT/CN2024/075400, filed on Feb. 2, 2024, which claims priority to Chinese Patent Application No. 202311604122.7, filed on Nov. 28, 2023, which is incorporated by reference for all purposes as if fully set forth herein.

### FIELD OF THE INVENTION

The present invention relates to the technical field of flexible electronics, and in particular to an air-permeable stretchable circuit, which can be activated by stamping, a method and use thereof.

### DESCRIPTION OF THE RELATED ART

Stretchable electronics and systems have been of great interest for their use in wearable electronics, soft-robotics, human-machine interfaces, and bioelectronics. A key aspect of stretchable electronics is the development of stretchable conductors. Many studies have focused on the creation of macroscopic deformable conductors by incorporating rigid conductors such as metal nanowires or conductive polymers into elastomeric substrates by means of bending, wrinkle design, dispersion or the like. However, the inherent rigidity of the electrically conductive material tends to compromise the stability of the stretchable conductors during prolonged deformations. Problems such as segregation of the metal nanowires under repeated external forces and cracking of the conductive polymer result in an irreversible decrease in conductivity of the stretchable conductor. In contrast, gallium-based liquid metals (LM) are also of great concern for their excellent deformability, while having an extremely high electrical conductivity at room temperature.

To avoid the challenges caused by the low viscosity and high surface tension of liquid metals and the spontaneous formation of non-conductive Ga₂O₃ oxide layers, liquid metal-based wires often require complex manufacturing processes such as sintering, transfer printing, or doping processes. These complexities limit the expandability and flexibility of stretchable electronics In addition, the elastic substrate commonly used in stretchable conductors is a water-proof film with poor adhesion and compatibility with human skin. This makes it less suitable for long-term applications, such as medical care monitoring, and may even have an inflammatory or allergic effect on health. Nanofiber webs that can be loaded with liquid metal have recently received attention because the liquid metal can penetrate the gaps of the nanofibers through coating or spraying to form a grid-like conductive pathway during stretching. The resulting materials have high conductivity and extensibility while maintaining good air permeability. Since the surface tension of liquid metals is high and the interface compatibility with the polymer fiber network is poor, macroscopically, the liquid metal and polymer network generally exhibit two layers, i. e. a liquid metal conductive layer and a polymer support layer. The adhesion between the two layers is poor, which tends to lead to leakage of liquid metal, so that the precision of the manufactured circuit is low, and thus it is difficult to achieve good cycle stretching stability, which has become a difficult problem in the industry. That is to say, the disadvantages of the current prior art are: 1. the existing stretchable circuits all lack the air permeability; 2. the current stretchable circuits have a relatively wide circuit path and a relatively low precision; 3. the activation of the conductive paths is difficult, and it is difficult to prepare rapidly.

Therefore, how to manufacture a stable and accurate conductive circuit and how to alleviate a serious interface problem between a liquid metal and a substrate elastic network have become urgent problems to be solved.

### SUMMARY OF THE INVENTION

To resolve the foregoing technical problems, the present invention provides an air-permeable stretchable circuit which can be activated by stamping, a preparation method and use thereof. The present invention can ensure air permeability and stretchability by using the nanofiber membrane. Since the liquid metal particles match the fiber diameter, the liquid metal inside the nanofiber can escape through stamping to form a conductive path, and thus the circuit can be prepared with high precision.

The present invention is achieved by the following technical solutions.

A first object of the present invention is to provide a method for preparing an air-permeable stretchable circuit, which can be activated by stamping, comprising the following steps of:
dissolving a thermoplastic polymer in a solvent, adding liquid metal particles and mixing to obtain a mixed solution;
performing electrospinning on the mixed solution to prepare a nanofiber membrane;
performing a stamping on the nanofiber membrane with a stamping mould having a circuit pattern, to obtain the air-permeable stretchable circuit which can be activated by stamping.

In an embodiment of the present invention, the thermoplastic polymer is selected from the group consisting of polyurethane, PVDF, PVDF-HFP, PVA, SBS SEBS, and any combination thereof.

In an embodiment of the present invention, the solvent is selected from the group consisting of hexafluoroisopropanol, tetrahydrofuran, acetone, N,N-dimethylformamide, N,N-dimethylacetamide, water, dichloromethane and any combination thereof.

In an embodiment of the present invention, the metal in the liquid metal particles is selected from the group consisting of gallium, gallium-indium alloy, gallium-indium-tin alloy, indium-tin-bismuth alloy and any combination thereof.

In an embodiment of the present invention, the liquid metal particles are prepared by the following method:
subjecting the metal to ultrasonic treatment in an alcohol to obtain the liquid metal particles.

In one embodiment of the present invention, the mass ratio of the liquid metal particles to the thermoplastic polymer in the thermoplastic polymer solution is 4-10:1.

In one embodiment of the present invention, the diameter ratio of the liquid metal particles to the fiber in the nanofiber membrane is 1:0.35-2.

In one embodiment of the present invention, the electrospinning satisfies one or more of the following conditions:
the size of the needle is 20 G-24 G;
the applied voltage is 6 kV-15 kV;
the feed rate of solution is 0.5 mL h⁻¹-1.2 mL h⁻¹;
the distance of fiber collection is 8 cm-16 cm;
the rotate speed of a metal roller for collecting the fiber membrane is 120 rpm-200 rpm.

The humidity for electrospinning is 40%.

In one embodiment of the present invention, the stamping condition is that a pressure intensity on the contact surface of the nanofiber membrane is from 100 kPa to 1 MPa.

A second object of the present invention is to provide an air-permeable stretchable circuit prepared by the above method.

A third object of the present invention is to provide Use of the air-permeable stretchable circuit in wearable electronics, soft robots, man-machine interfaces or bioelectronic devices.

Compared with the prior art, the technical solutions of the present invention have the following advantages:

In the present invention, an air-permeable stretchable circuit which can be activated by stamping is provided, which utilizes imprinting technology and a nanofiber membrane containing liquid metal (LMNM) to create flexible personalized circuits. By selecting appropriate liquid metal particles and electrospun fibers, the stretchable nanofiber membrane exhibits outstanding characteristics under high liquid metal loads, such as superelasticity (up to 400%) and moisture permeability (2941 g m⁻²d⁻¹). Initially, the liquid metal particles are partially embedded and unconnected within the polymer nanofibers, and the stretchable nanofiber membrane is electrically insulated. Stamping processes cause external liquid metal particles to rupture and penetrate the gaps of nanonetworks, thereby forming conductive regions within the stretchable nanofiber membrane. the liquid metal particles within the fibers act as fixed anchor points, while the spilled liquid metal tightly bind with the nanofibers on the same plane, significantly enhancing the interfacial compatibility between the liquid metal and polymer fibers. This process facilitates the subsequent fabrication of patterned circuits, providing greater flexibility for personalized circuit designs. Upon integration with various electronic components, these circuits can perform multiple functions such as outputing square signals, illuminating circuits, and wireless charging. Additionally, the manufactured flexible electronic components exhibit high precision, with a minimum line width of 50 micrometers, excellent cycling stability, and a lifespan of over 30,000 cycles. Their excellent biocompatibility and permeability make them suitable for collecting bioelectrical signals, such as electrocardiograms (ECG) and electromyograms (EMG), thus presenting broad prospects in the field of flexible electronics. This technology is also considered environmentally friendly, as both polymer components and liquid metal particles can be conveniently separated and recycled after use. Furthermore, experimental studies have been conducted on various commonly used polymers for preparing stretchable nanofiber membranes, demonstrating the significant potential of this technology in the field of flexible electronics.

### BRIEF DESCRIPTION OF THE DRAWINGS

To make the content of the present invention clearer and more comprehensible, the present invention is further described in detail below according to specific embodiments of the present invention and the accompanying draws. Where:

FIG. 1 is a schematic diagram of a preparation process of an air-permeable stretchable circuit which can be activated by stamping according to the present invention;

FIG. 2 is a circuit schematic diagram in embodiment 1 of the present invention;

FIG. 3 is a schematic diagram of the stretchable luminous circuit in embodiment 1 of the present invention;

FIG. 4 shows the diameter distribution of liquid metal particles of different sizes in the test example of the present invention;

FIG. 5 shows the resistance and conductivity of a nanofiber membrane containing liquid metal particles of different sizes after stamping in test example of the present invention;

FIG. 6 shows the fiber diameter corresponding to different liquid metal contents in a test example of the present invention;

FIG. 7 shows the stress-strain curve of the circuit with different liquid metal loadings in a test example of the present invention;

FIG. 8 shows the strain-impedance curve of the circuit with different liquid metal loadings in a test example of the present invention;

FIG. 9 shows the impedance stability of the circuit under cyclic stretching in a test example of the present invention;

FIG. 10 shows the air permeability of the circuit under different pressure differentials in a test example of the present invention;

FIG. 11 shows scanning electron microscope images of conductive lines with different widths (50 micrometers, 100 micrometers, 500 micrometers, and 1 millimeter) in a test example of the present invention;

FIG. 12 shows the template used for stamping and the circuit prepared after stamping in a test example of the present invention;

FIG. 13 shows the conductivity test graph of the nanofiber membrane circuit in a test example of the present invention.

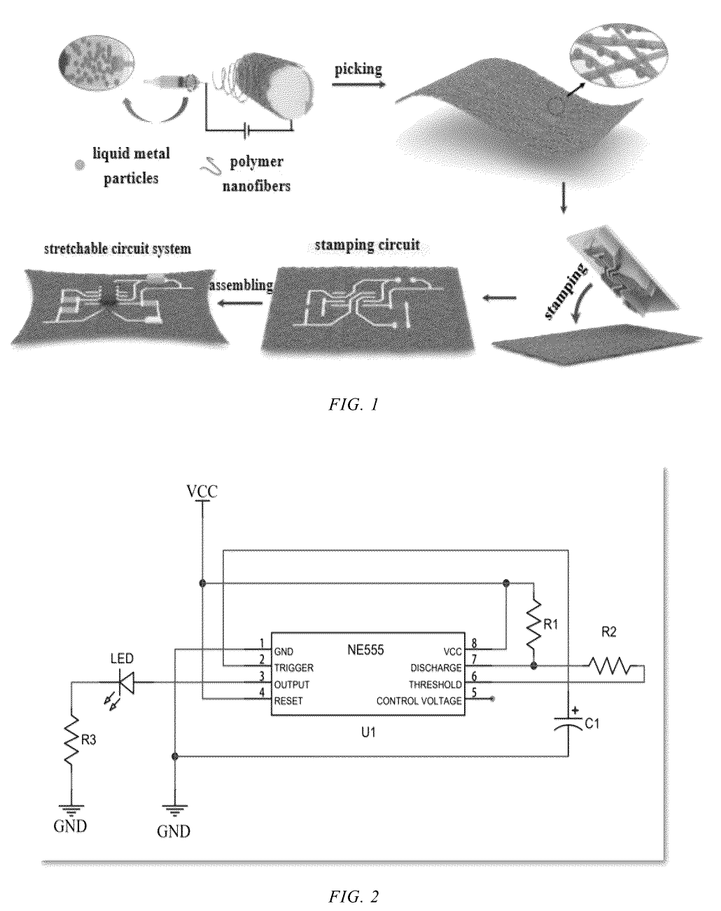

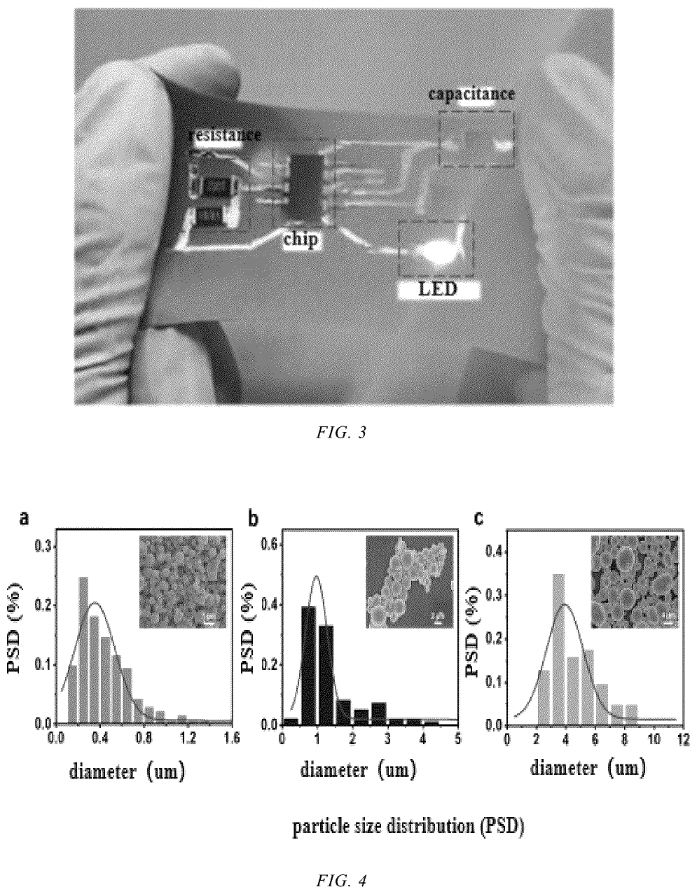

### DETAILED DESCRIPTION OF THE PREFERRED EMBODIMENTS

The present invention is further described below with reference to the accompanying drawings and specific embodiments, to enable a person skilled in the art to better understand and implement the present invention. However, the embodiments are not used to limit the present invention.

### Embodiment 1

This embodiment provides an air-permeable stretchable circuit, which can be activated by stamping, comprising the following steps:

### (1) Preparation of Composite Spinning Solution

1 g of thermoplastic polyurethane was dissolved in 19 g of hexafluoroisopropanol and stirred at room temperature for 12 hours to prepare a polymer solution. 1 g of EGaIn eutectic alloy was placed in 5 g of anhydrous ethanol and sonicated in a 10 mL centrifuge tube to prepare liquid metal particles. The liquid metal particles were sonicated at 50% power in an ultrasonic cell disruptor for 5 minutes, with the centrifuge tube placed in an ice bath throughout the sonication process. The obtained liquid metal slurry was centrifuged at a speed of 100 rpm for 60 s; the supernatant was retained and then centrifuged at a speed of 500 rpm for 90 s to remove the supernatant. The remaining slurry was vacuum dried at room temperature for 6 hours. Finally, the liquid metal particles were added to the polymer solution in a certain mass ratio (liquid metal particle mass:polymer solution mass=8:1) and stirred for two hours at room temperature to ensure uniform dispersion of the particles in the solution.

### (2) Preparation of Nanofiber Membrane by Electrospinning

The mixed solution containing the polymer solution and the liquid metal particles was loaded into a 10 mL syringe for electrospinning using an electrospinning machine. During electrospinning, the needle size, applied voltage, solution feeding rate, and fiber collection distance were set to 23 G, 12 kV, 1 mL h⁻¹, and 12 cm, respectively. The fiber membrane was collected by a metal roller with a rotation speed of 110 rpm. The entire process was carried out at room temperature with humidity controlled at 40%, and the syringe was rotated every 2 hours to prevent sedimentation of liquid metal particles in the solution. Finally, the electrospun fiber membrane was placed in an oven at 40° C. for 6 hours to remove residual solvent.

### (3) Activation of Conductive Network by Pressure Stamping

A pressure of 500 kPa was applied to the nanofiber membrane using a stamping mold with the desired circuit pattern to obtain a stretchable circuit board with patterned circuits. The liquid metal loading of the obtained stretchable circuit board was 40 wt %, and the ratio of the diameter of liquid metal particles to the diameter of fibers in the nanofiber membrane was 1:0.5-2.

### Embodiment 2

This embodiment provides an air-permeable stretchable circuit, which can be activated by stamping, comprising the following steps:

### (1) Preparation of Composite Spinning Solution

1 g of PVDF-HFP was dissolved in 9 g of DMF and stirred at room temperature for 12 hours to prepare a polymer solution. 1 g of EGaIn eutectic alloy was placed in 5 g of anhydrous ethanol and sonicated in a 10 mL centrifuge tube to prepare liquid metal particles. The liquid metal particles were sonicated at 50% power in an ultrasonic cell disruptor for 5 minutes, with the centrifuge tube placed in an ice bath throughout the sonication process. The obtained liquid metal slurry was centrifuged at a speed of 100 rpm for 60 s; the supernatant was retained and then centrifuged at a speed of 500 rpm for 90 s to remove the supernatant. The remaining slurry was vacuum dried at room temperature for 6 hours. Finally, the liquid metal particles were added to the polymer solution in a certain mass ratio (liquid metal particle mass:polymer solution mass=3:1) and stirred for two hours at room temperature to ensure uniform dispersion of the particles in the solution.

### (2) Preparation of Nanofiber Membrane by Electrospinning

The mixed solution containing the polymer solution and the liquid metal particles was loaded into a 10 mL syringe for electrospinning using an electrospinning machine. During electrospinning, the needle size, applied voltage, feed rate of solution, and distance of fiber collection were set to 22 G, 14 kV, 1 mL h⁻¹, and 15 cm, respectively. The fiber membrane was collected by a metal roller with a rotation speed of 110 rpm. The entire process was carried out at room temperature with humidity controlled at 40%, and the syringe was rotated every 2 hours to prevent sedimentation of liquid metal particles in the solution. Finally, the electrospun fiber membrane was placed in an oven at 40° C. for 6 hours to remove residual solvent.

### (3) Activation of Conductive Network by Pressure Stamping

A pressure of 300 kPa was applied to the nanofiber membrane using a stamping mold with the desired circuit pattern to obtain a stretchable circuit board with patterned circuits. The liquid metal loading of the obtained stretchable circuit board was 30 wt %, and the ratio of the diameter of liquid metal particles to the diameter of fibers in the nanofiber membrane was 1:0.35-1.5.

### Test Example

(1) The liquid metal slurry obtained from the ultrasonic cell crushing system can be separated into liquid metal particles of different particle sizes by centrifugation at different speeds and room temperature vacuum drying; the average particle sizes obtained by Gaussian fitting were 0.36 μm, 0.99 μm, and 3.95 μm, respectively. Nanofiber membranes with different particle sizes of liquid metal particles were prepared by the method of embodiment 1.

Nanofiber membranes containing liquid metal particles of different sizes were tested for resistance and conductivity after stamping, and the results are shown in FIG. 5. Among them, the nanofiber membrane (a) can be activated by stamping, with an average particle size of 0.99 μm (embodiment 1), matching the size of the nanofibers; while (b) is a nanofiber membrane with liquid metal particle size of 0.36 μm, which does not match the size of the nanofibers and can not be activated by stamping. Liquid metal particles with an average size of 3.95 μm were difficult to be stably encapsulated by fibers due to their large volume, resulting in misleading conduction before stamping, and therefore were not adopted.

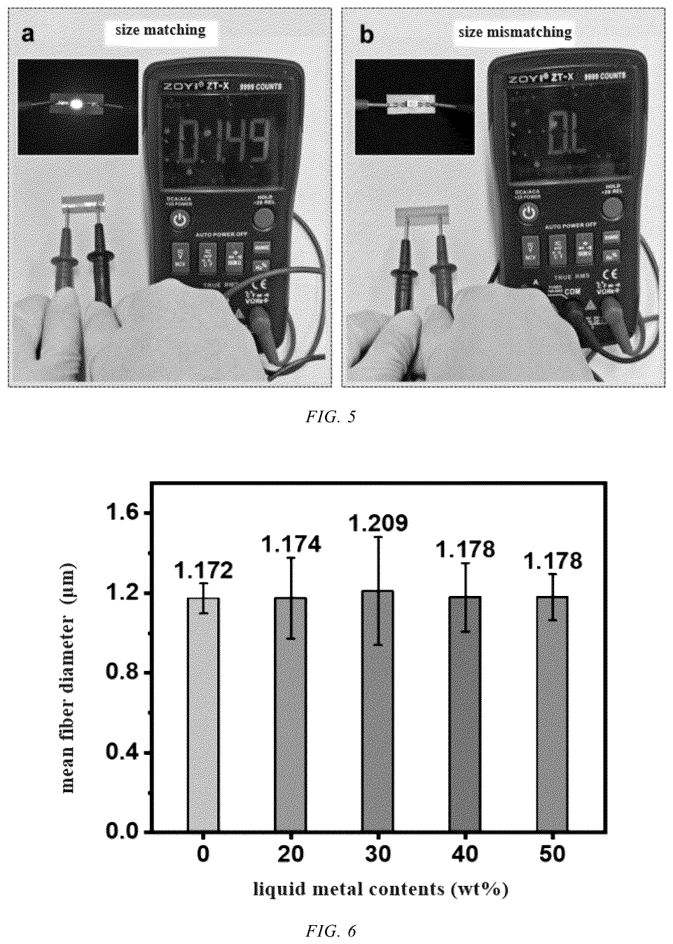

(2) Nanofiber membranes with different liquid metal loading amounts (20 wt %, 30 wt %, 40 wt %, and 50 wt %) were prepared by the method of Embodiment 1, and the stretchable circuit boards with patterned circuits were obtained after stamping. The diameter of the nanofibers in the nanofiber membranes was tested, and the results are shown in FIG. 6. It can be seen from FIG. 6 that the loading amount of liquid metal has little effect on the diameter of nanofibers.

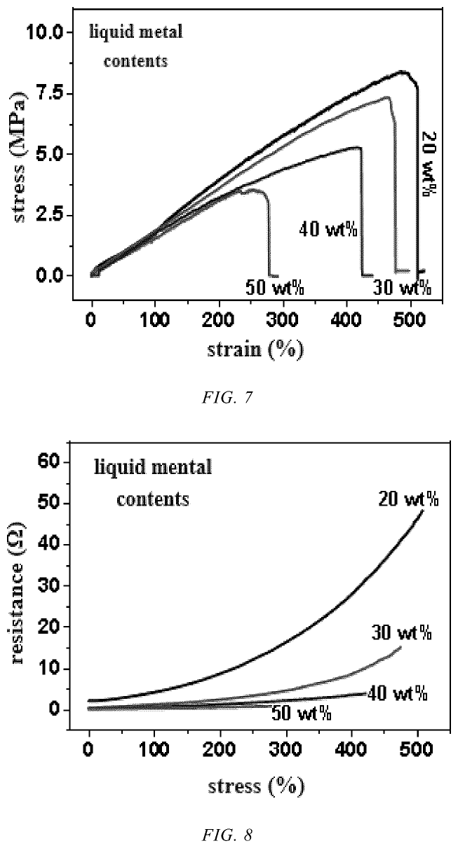

The mechanical properties of elongated samples with dimensions of 50 mm×10 mm were evaluated using a tensile testing machine (Instron), as shown in FIG. 7. FIG. 7 confirms that circuits with different liquid metal loading amounts are overall stretchable, and the lower the metal loading amount, the stronger the stretchability.

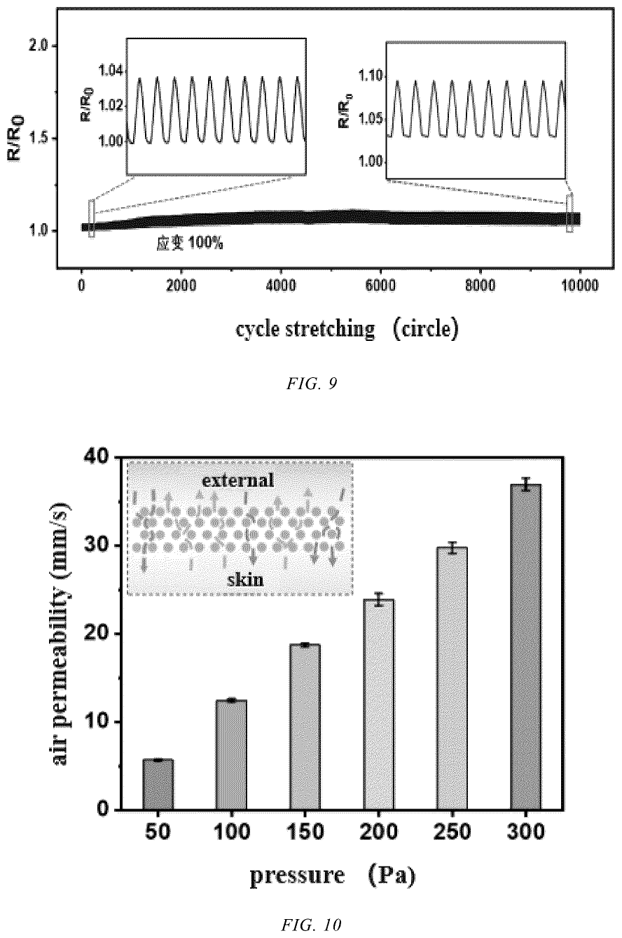

The air-permeable stretchable circuits with different liquid metal loading amounts (20 wt %, 30 wt %, 40 wt %, and 50 wt %) were connected to a Keithley DMM6500 connected to a computer to measure the change in sample resistance during stretching, using the four-terminal method to accurately measure the resistance change of the sample and avoid interference. The results are shown in FIG. 8, from which it can be seen that the higher the metal loading amount, the higher the circuit conductivity; cyclic stretching of the stretchable circuit under 40 wt % metal loading was performed, and the results are shown in FIG. 9, confirming the high impedance stability of the circuit under cyclic stretching at 40 wt % metal loading.

(3) According to ASTM E96/E96M-2012 textile standards, the water permeability of the sample was determined by the water method under 32° C. and 50% relative humidity for 24 hours. Samples with a liquid metal loading of 40 wt % were sealed on the mouth of a cup filled with water and then placed in the test environment. The weight loss of water during this period was measured to determine the mass of water vapor permeated. According to ASTM D737-75 standard test method, the air permeability was measured under different pressure drops using a fully automatic air permeability instrument (YG461G, Ningbo Dahe Instrument Co., Ltd.). The output air flow rate (unit: mm/second) represents the permeability of the sample, as shown in FIG. 10. It can be seen from FIG. 10 that the stretchable circuits prepared by the present invention overall have moisture permeability and air permeability.

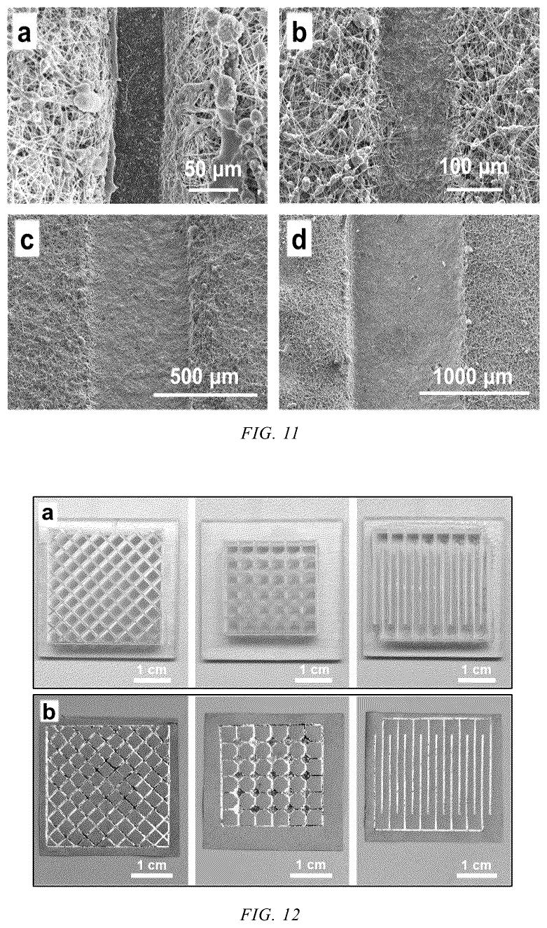

(4) The air-permeable stretchable circuits with different conductive line widths (50 μm, 100 μm, 500 μm and 1000 μm) are prepared according to the method of embodiment 1, wherein the conductive line width is characterized by a scanning electron microscope (Regulus 8230), as shown in FIG. 11, and it is confirmed from FIG. 11 that the precision of the minimum line width of the circuit is high.

(5) circuit design is performed using the Altium Designer software, and a corresponding three-dimensional model is made using the SolidWorks software. A stamping mold with a desired pattern is made using a three-dimensional printer (Zortrax Inkspire), and then stamping is performed on the nanofibrous membrane prepared in embodiment 1 using a pneumatic press (LNA001-63). As shown in FIG. 12, it is confirmed that different circuits can be prepared by stamping technology.

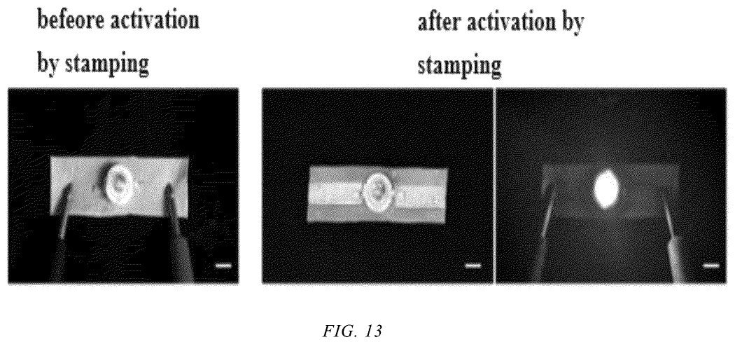

(6) Power is supplied to the nanofibrous membrane prepared in embodiment 2 using a constant voltage power supply, and the on/off of a light-emitting diode is used as a test for the conductivity of a circuit; and as shown in FIG. 13, it is confirmed that the stamping technology can achieve the conversion from non-conduction to conduction of the nanofibrous membrane.

Obviously, the foregoing embodiments are merely examples for clear description, rather than a limitation to implementations. For a person of ordinary skill in the art, other changes or variations in different forms may also be made based on the foregoing description. All implementations cannot and do not need to be exhaustively listed herein. Obvious changes or variations that are derived therefrom still fall within the protection scope of the present invention.

What is claimed is:

1. A method for preparing an air-permeable stretchable circuit, which can be activated by stamping, comprising steps of:
dissolving a thermoplastic polymer in a solvent, then adding liquid metal particles and mixing to obtain a mixed solution;
performing electrospinning on the mixed solution to prepare a nanofiber membrane;
performing stamping on the nanofiber membrane with a stamping mould having a circuit pattern, to obtain the air-permeable stretchable circuit.

2. The method according to claim 1, wherein the thermoplastic polymer is selected from the group consisting of polyurethane, PVDF, PVDF-HFP, PVA, SBS, SEBS and any combination thereof.

3. The method of claim 1, wherein the solvent is selected from the group consisting of hexafluoroisopropanol, tetrahydrofuran, acetone, N,N-dimethylformamide, N,N-dimethylacetamide, water, dichloromethane and any combination thereof.

4. The method according to claim 1, wherein the metal in the liquid metal particles is selected from the group consisting of gallium, gallium-indium alloy, gallium-indium-tin alloy, indium-tin-bismuth alloy and any combination thereof.

5. The method according to claim 1, wherein a mass ratio of the liquid metal particles to the thermoplastic polymer in the thermoplastic polymer solution is 4-10:1.

6. The method according to claim 1, wherein a diameter ratio of the liquid metal particles to the fiber in the nanofiber membrane is 1:0.35-2.

7. The method according to claim 1, wherein the electrospinning satisfies one or more of following conditions:
a size of the needle is 20 G-24 G;
an applied voltage is 6 kV-15 kV;
a feed rate of solution is 0.5 mL h⁻¹-1.2 mL h⁻¹;
a distance of fiber collection is 8 cm-16 cm; and
a rotate speed of a metal roller for collecting the fiber membrane is 120 rpm-200 rpm.

8. The method according to claim 1, wherein a stamping condition is that a pressure intensity on a contact surface of the nanofiber membrane is from 100 kPa to 1 MPa.

9. An air-permeable stretchable circuit prepared according to the method of claim 1.

10. Use of the air-permeable stretchable circuit according to claim 9 in wearable electronics, soft robots, man-machine interfaces or bioelectronic devices.
